(19) United States
(12) Patent Application Publication
(10) Pub. No.: US 2007/0278474 A1
(43) Pub. Date: Dec. 6, 2007

(54) Semiconductor light emitting element

(75) Inventors: Kazuaki Tsutsumi, Kyoto (JP); Norikazu Ito, Kyoto (JP); Masayuki Sonobe, Kyoto (JP); Hiroaki Ohta, Kyoto (JP)

Correspondence Address: HAMRE, SCHUMANN, MUELLER & LARSON, P.C., P.O. BOX 2902, MINNEAPOLIS, MN, 55402-0902, US

(73) Assignee: ROHM CO., LTD., Kyoto-shi (JP)

(21) Appl. No.: 11/789,035

(22) Filed: Apr. 23, 2007

(30) Foreign Application Priority Data
Apr. 28, 2006 (JP) 2006-125177

(51) Int. Cl. H01L 31/0312

(52) U.S. Cl. 257/13; 257/E31.023; 257/E31.127

(57) ABSTRACT

A semiconductor light emitting element includes an active layer of a quantum well structure, and an n-type semiconductor layer and a p-type semiconductor layer, formed to hold the active layer therebetween. The active layer includes at least a well layer containing InGaN, and at least two barrier layers formed to hold the well layer therebetween, and containing one of InGaN and GaN. The well layer is entirely doped with one of a group IV element and a group VI element. The respective barrier layer includes a first portion closer to the p-type semiconductor layer and a second portion closer to the n-type semiconductor layer. The first portion is doped with one of the group IV element and the group VI element. The second portion is undoped.

### BACKGROUND OF THE INVENTION

1. Field of the Invention

The present invention relates to a semiconductor light emitting element that includes an active layer having a quantum well structure.

2. Description of the Related Art

Semiconductor light emitting elements include a light emitting diode and a semiconductor laser. Various techniques have so far been proposed for improving the light emitting efficiency of the semiconductor light emitting element. To cite one, JP-A No. 2004-179428 teaches utilizing a quantum well structure in the active layer, as an example of those techniques.

FIG. 7 depicts a conventional semiconductor light emitting element. The semiconductor light emitting element X shown therein includes an n-GaN layer 91, a p-GaN layer 92, and an active layer 93. The active layer 93 is of a multiple quantum well (MQW) structure including a plurality of well layers 94 and a plurality of barrier layers 95 alternately layered. The well layer 94 is constituted of InGaN, while the barrier layer 95 of GaN. The well layer 94 has a smaller bandgap energy than that of the n-GaN layer 91, the p-GaN layer 92, and the barrier layer 95. Such structure facilitates locking in a carrier (an electron and a hole) in the well layer 94, which enhances efficient recoupling of the electron and the hole, thereby improving the light emitting efficiency.

Such type of semiconductor light emitting element is now required to provide higher luminance, yet under a lower output. For reducing the output of the semiconductor light emitting element X, it is effective to decrease the forward voltage Vf. Simply employing the MQW structure, however, does not permit sufficiently decreasing the forward voltage Vf. Thus, the semiconductor light emitting element X still has room for improvement in the aspect of output reduction.

### SUMMARY OF THE INVENTION

The present invention has been proposed under the foregoing situation. An object of the present invention is to provide a semiconductor light emitting element that offers higher luminance under a lower output.

According to the present invention, there is provided a semiconductor light emitting element that includes an active layer of a quantum well structure. The active layer includes at least one well layer containing InGaN, and at least two barrier layers flanking the well layer therebetween and containing InGaN or GaN. The semiconductor light emitting element of the present invention also includes an n-type semiconductor layer and a p-type semiconductor layer, arranged to flank the active layer therebetween. The well layer is entirely doped with a group IV element or a group VI element. The respective barrier layer includes a first portion closer to the p-type semiconductor layer and a second portion closer to the n-type semiconductor layer. The first portion is doped with the group IV element or the group VI element. The second portion is undoped.

Preferably, the group IV element may be Si, while the group VI element may be O. The average doping concentration of the group IV or the group VI element in the active layer may be 9×10¹⁶ to 5×10¹⁸ atoms/cm³. More preferably, the average doping concentration may be 9×10¹⁶ to 5×10¹⁷ atoms/cm³.

Other features and advantages of the present invention will become more apparent through the following detailed description made with reference to the accompanying drawings.

### BRIEF DESCRIPTION OF THE DRAWINGS

FIG. 1 is a cross-sectional view of a semiconductor light emitting element according to the present invention;

FIG. 2 is a cross-sectional view of an active layer in the semiconductor light emitting element of FIG. 1;

FIG. 3 is a graph showing relative forward voltages according to an inventive example 1 and comparative examples 1, 2;

FIG. 4 is a diagram showing a bandgap energy of the active layer in the semiconductor light emitting element of FIG. 1;

FIG. 5 is a graph showing a relationship between Si doping concentration and the forward voltage; and

FIG. 6 is a cross-sectional view of a conventional semiconductor light emitting element.

### DETAILED DESCRIPTION OF THE PREFERRED EMBODIMENT

Hereunder, a preferred embodiment of the present invention will be described with reference to the drawings.

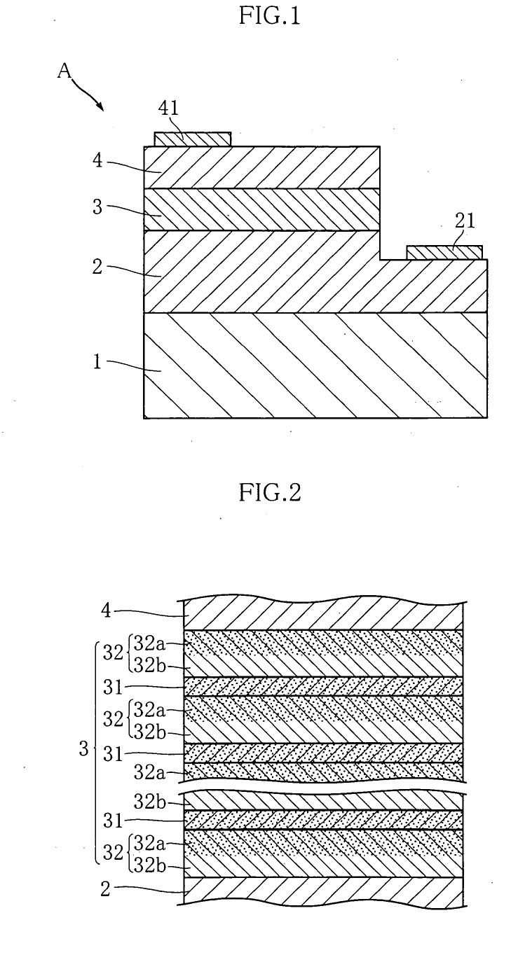

FIGS. 1 and 2 depict a semiconductor light emitting element according to the present invention. The semiconductor light emitting element A shown therein includes a substrate 1, an n-GaN layer 2, an active layer 3, and a p-GaN layer 4. The semiconductor light emitting element A is designed to emit, for example, blue light upwardly according to the orientation of FIG. 1.

The substrate 1 is for example constituted of sapphire, and serves to support the n-GaN layer 2, the active layer 3, and the p-GaN layer 4. The substrate 1 may have a thickness of approximately 300 to 500 μm.

The n-GaN layer 2 is constituted as a so-called n-type semiconductor layer, because of doping of Si on GaN. The n-GaN layer 2 includes thick-wall portion having a relatively greater thickness, and a thin-wall portion which is relatively thinner. On an upper surface of the thin-wall portion, an n-side electrode 21 is provided. The thick-wall portion may have a thickness of approximately several microns.

Between the n-GaN layer 2 and the active layer 3, a super lattice layer, an n-type clad layer, and an n-type guide layer may be provided, as the case may be. The super lattice layer has a super lattice structure in which for example an InGaN atomic layer of and a GaN atomic layer are alternately layered. The n-type clad layer is for example constituted of AlGaN doped with an n-type impurity, and serves to prevent the light from the active layer 3 from leaking toward the n-GaN layer 2. The n-type guide layer is for example constituted of InGaN doped with an n-type impurity, and serves to lock in an electron and a hole, which are carriers, in the active layer 3.

The active layer 3 is constituted as a MQW structure containing InGaN, and serves to amplify the light emitted by the recoupling of the electron and the hole. The active layer 3 includes a plurality of well layers 31 and a plurality of barrier layers 32 alternately layered. The active layer 3 includes, for example, 3 to 7 layers each of the well layer 31 and the barrier layer 32. The active layer 3 may have a thickness of approximately 50 to 150 nm.

The well layer 31 is constituted of InGaN, with an In content of approximately 10 to 20%. Because of such composition, the well layer 31 has lower bandgap energy than the n-GaN layer 2. Also, the well layer 31 is doped with a group IV element (for example, Si) or a group VI element (for example, O) over an entire region thereof. Preferably, the doping concentration of the group IV element or the group VI element is 9×10¹⁶ to 5×10¹⁸ atoms/cm³, and more preferably 9×10¹⁶ to 5×10¹⁷ atoms/cm³. The well layer 31 may have a thickness of approximately 20 to 35 Å.

The barrier layer. 32 is constituted of InGaN with a lower In content than the well layer 31, or of GaN. The barrier layer 32 includes a doped portion 32a and an undoped portion 32b. The doped portion 32a occupies a portion of the barrier layer 32 closer to the p-GaN layer 4, and has, for example, approximately half a thickness of the barrier layer 32. The doped portion 32a is doped with a group IV element (for example, Si) or a group VI element (for example, O). Preferably, the doping concentration of the group IV element or the group VI element is 9×10¹⁶ to 5×10¹⁸ atoms/cm³, and more preferably 9×10¹⁶ to 5×10¹⁷ atoms/cm³. The barrier layer 32 may have a thickness of approximately 70 to 180 Å.

The p-GaN layer 4 is constituted as a p-type semiconductor layer, because of doping of Mg on GaN. The p-GaN layer 4 is, for example, approximately 0.2 μm in thickness. The p-GaN layer 4 includes a p-side electrode 41.

The present inventors made up an inventive example 1 (semiconductor light emitting element A) and comparative examples 1, 2 for comparison therewith, and studied on the characteristics of those examples.

The inventive example 1 was made up as follows. Firstly the substrate 1 was introduced into a chamber of a metal organic chemical vapor deposition (MOCVD) apparatus, and the temperature inside the deposition chamber (hereinafter, “deposition temperature”) was set at 1100° C. Under such state, H₂ gas and N₂ gas were introduced into the deposition chamber, thereby cleaning the substrate 1.

Then the deposition temperature was set at 1060° C., and NH₃ gas, H₂ gas, N₂ gas, and organic metal gallium (for example, trimethyl gallium, hereinafter abbreviated as TMG) gas were introduced into the deposition chamber. At the same time, SiH₄ gas was supplied for doping Si, which is the n-type dopant. As a result, the n-GaN layer 2 was formed. on the substrate 1. In the formation process of the n-GaN layer, the organic metal gallium gas is acting as a supply source of Ga.

The deposition temperature was then set in a range of 700 to 800° C. (for example, 760° C.), and NH₃ gas, H₂ gas, N₂ gas, and Ga source gas (for example, TMG gas) were supplied. This process led to formation of the undoped portion 32b of the barrier layer 32 constituted of GaN. The undoped portion 32b was formed in a thickness of 60 Å.

Under the deposition temperature of 760° C., NH₃ gas, H₂ gas, N₂ gas, Ga source gas, and SiH₄ gas for doping Si were then supplied. This process led to formation of the doped portion 32b of the barrier layer 32 constituted of GaN. The doping concentration in the doped portion 32a was set at 2.0×10¹⁷ atoms/cm³. The doped portion 32a was formed in a thickness of 60 Å, as the undoped portion 32b. The doped portion 32a and the undoped portion 32b were stacked, to form the barrier layer 32 having the thickness of 120 Å.

Then under the deposition temperature of approximately 760° C., NH₃ gas, H₂ gas, N₂ gas, Ga source gas, and In source gas (for example, trimethyl indium gas, hereinafter abbreviated as TMIn gas) were introduced into the deposition chamber. At the same time, SiH₄ gas for doping Si was also supplied. This process led to formation of the well layer 31 constituted of InGaN, with the In content of approximately 15%. The doping concentration of Si in the well layer 31 was set at 2.0×10¹⁷ atoms/cm³, as the doped portion 32a. The well layer 31 was formed in a thickness of 30 Å.

The well layer 31 and the barrier layer 32 were then alternately formed. Upon forming 3 to 7 layers of the respective layers, the active layer 3 having the MQW structure was obtained. The average Si doping concentration of the active layer 3 as a whole was 1.2×10¹⁷ atoms/cm³.

Then the deposition temperature was set at 1010° C., and NH₃ gas, H₂ gas, N₂ gas, and Ga source gas (for example, TMG gas) were supplied. At the same time, Cp₂Mg gas was also supplied, for doping Mg which is the p-type dopant. As a result, the p-GaN layer 4 was formed. Thereafter, upon forming the n-side electrode 21 and the p-side electrode 41, the semiconductor light emitting element of the inventive example 1 was obtained.

Through similar steps, the comparative examples 1 and the comparative example 2 were fabricated. Differences of these examples from the inventive example 1 are as follows. In the comparative example 1, Si was doped all over the well layer 31 and the barrier layer 32, in a doping concentration of 2.0×10¹⁷ atoms/cm³. In the comparative example 2, the well layer 31 and a portion corresponding to the undoped portion 32b of the inventive example 1 were doped with Si in a doping concentration of 2.0×10¹⁷ atoms/cm³, while a portion corresponding to the doped portion 32a of the inventive example 1 was not doped with Si. As a result, the average Si doping concentration on the active layer 3 of the comparative example 2 was 1.2×10¹⁷ atoms/cm³, as the case of the inventive example 1.

The advantageous effects of the inventive example 1 (semiconductor light emitting element A) will now be described.

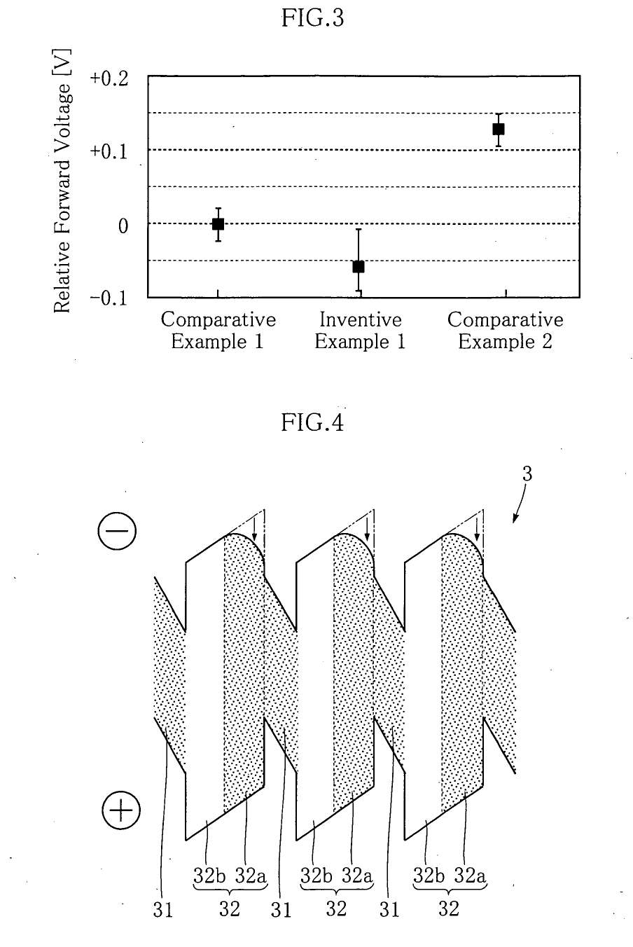

FIG. 3 indicates a forward voltage Vf required for generating a current of 20 mA, in the inventive example 1 and the comparative examples 1, 2. Here, the voltage is expressed as a relative value with respect to the forward voltage Vf of the comparative example 1 taken as the reference (0V). As shown in FIG. 3, the forward voltage Vf was decreased by 0.05 V in the inventive example 1, with respect to the comparative example 1, in which Si was doped all over the region corresponding to the well layer 31 and the barrier layer 32. Also, although the inventive example 1 and the comparative example 2 have the same average Si doping concentration in the active layer 3, the forward voltage Vf of the comparative example 2 was increased by 0.2 V, compared with the inventive example 1. Besides, the forward voltage Vf of the comparative example 2 is still higher than the comparative example 1, not only than the inventive example 1. Such result proves that the inventive example 1, in which Si was doped on the well layer 31 and the doped portion 32a of the barrier layer 32 closer to the p-GaN layer, is capable of decreasing the forward voltage Vf.

The forward voltage Vf can be decreased presumably for the following reason. FIG. 4 schematically illustrates the bandgap energy in the active layer 3. In the well layer 31, the bandgap energy is relatively smaller, while in the barrier layer 32 the bandgap energy is relatively greater. When the forward voltage Vf is applied to the inventive example 1 (semiconductor light emitting element A), an interface charge is generated at the boundary between the edge of the barrier layer 32 closer to the p-GaN layer 4 and the well layer 31. However, the Si doped in the doped portion 32a blocks the interface charge, thereby decreasing the forward voltage Vf.

The effect of decreasing the forward voltage Vf may also be attained by doping a group IV or a group VI element, without limitation to Si, on the well layer 31 and the doped portion 32a. The elements that provide such effect include C, which is a group IV element, and O which is a group VI element, in place of Si. Here, doping Si allows sharply changing the doping concentration in a thicknesswise direction of the active layer 3, in the formation process of the semiconductor light emitting element A. Such nature is, therefore, appropriate for performing the doping on the well layer 31 and the doped portion 32a in a desired doping concentration, while leaving the undoped portion 32b barely doped. Employing Si is also advantageous for alternately stacking the well layer 31/doped portion 32a and the undoped portion 32b, which have far different doping concentration.

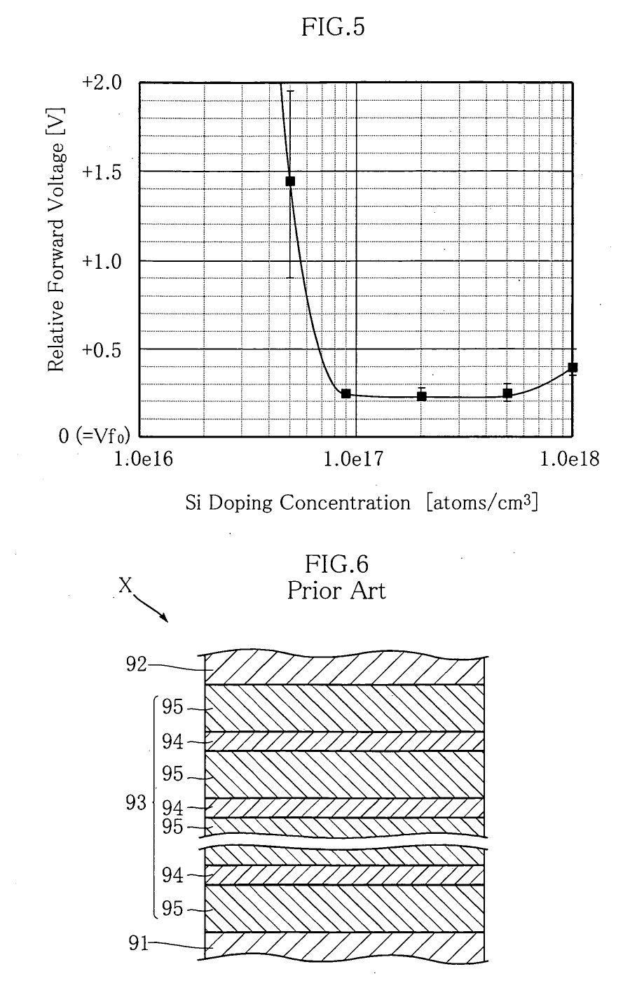

FIG. 5 shows a measurement result of the forward voltage Vf in the case of uniformly doping Si on the active layer 3. In FIG. 5, the forward voltage Vf is expressed as a relative value with respect to a certain forward voltage Vf₀, at each level of the doping concentration. As shown therein, setting the Si doping concentration in a range of 9×10¹⁶ to 5×10¹⁷ atoms/cm³ allows obtaining a minimal value of the forward voltage Vf. This proves that setting the average Si doping concentration over the entirety of the active layer 3 in a range of 9×10¹⁶ to 5×10¹⁷ atoms/cm³ is preferable for obtaining a minimal value of the forward voltage Vf.

Also, while the forward voltage Vf sharply increases when the Si doping concentration is lower than 9×10¹⁶ atoms/cm³, the increase in forward voltage Vf is relatively mild despite increasing the Si doping concentration than 5×10¹⁷ atoms/cm³. Through the relevant studies, the present inventors have established the finding that unless the average Si doping concentration exceeds 5×10¹⁸ atoms/cm³, the forward voltage Vf can be kept at a sufficiently low level for reducing the output of the semiconductor light emitting element A. It is also known that increasing the Si doping concentration results in lower luminance of the light emitted by the active layer 3. From such viewpoint, it is preferable to set the average Si doping concentration in a range of 9×10¹⁶ to 5×10¹⁷ atoms/cm³, for achieving a lower output of the semiconductor light emitting element compared with the conventional one, while preventing degradation in luminance.

It suffices that the active layer according to the present invention has a quantum well structure, including a single quantum well (SQW) structure, instead of the MQW structure. Although it is preferable, from the viewpoint of achieving higher luminance under a lower output, to employ n-GaN and p-GaN for constituting the n-type semiconductor layer and the p-type semiconductor layer respectively, other materials may be employed provided that an electron and a hole can be properly implanted on an active layer have a quantum well structure. Further, the semiconductor light emitting element according to the present invention may be designed to emit light either in an upper or lower direction according to the orientation of FIG. 1. The type of the light emitted by the active layer is not specifically limited. In addition, a color conversion layer may be provided, thus to enable emitting white light.

1. A semiconductor light emitting element, comprising:
an active layer including at least one well layer and at least two barrier layers flanking the well layer, the well layer containing InGaN, the barrier layers containing InGaN or GaN; and
an n-type semiconductor layer and a p-type semiconductor layer flanking the active layer;
wherein the well layer is entirely doped with a group IV element or a group VI element,
wherein each of the barrier layers includes a first portion closer to the p-type semiconductor layer and a second portion closer to the n-type semiconductor layer, the first portion being doped with the group IV element or the group VI element, the second portion being undoped.

2. The semiconductor light emitting element according to claim 1, wherein the group IV element is Si, and the group VI element is O.

3. The semiconductor light emitting element according to claim 1, wherein an average doping concentration of the group IV or group VI element in the active layer is in a range of 9×10₁₆ to 5×10¹⁸ atoms/cm³.

4. The semiconductor light emitting element according to claim 1, wherein an average doping concentration of the group IV or group VI element in the active layer is in a range of 9×10¹⁶ to 5×10¹⁷ atoms/cm³.
